(19) United States
(12) Patent Application Publication
(10) Pub. No.: US 2007/0025406 A1
(43) Pub. Date: Feb. 1, 2007

(54) Semiconductor laser array and semiconductor laser device

(75) Inventors: Masanori Yamada, Kanagawa-ken (JP); Kazuya Tsunoda, Kanagawa-ken (JP); Koichi Matsushita, Kanagawa-ken (JP); Hironobu Miyasaka, Kanagawa-ken (JP)

Correspondence Address: BANNER & WITCOFF, LTD., ATTORNEYS FOR RESERVE;ATTORNEYS FOR CLIENT NO. 000449, 001701, 1001 G STREET, N.W., 11TH FLOOR, WASHINGTON, DC, 20001-4597, US

(73) Assignee: Kabushiki Kaisha Toshiba, Tokyo (JP)

(21) Appl. No.: 11/493,036

(22) Filed: Jul. 26, 2006

(30) Foreign Application Priority Data
Jul. 26, 2005 (JP) 2005-215963

(51) Int. Cl. H01S 5/00

(52) U.S. Cl. 372/50.121

(57) ABSTRACT

A semiconductor laser array is described. The semiconductor laser array may include a plurality of semiconductor laser elements including a first laser element and a second laser element. The first laser element may be configured to emit a shorter wavelength laser than the second laser element. The emission portion of the first laser element provided substantially on a center line of a substrate.

### CROSS REFERENCE TO RELATED APPLICATION

This application is based upon and claims the benefit of priority from Japanese Patent Application No. P2005-215963, filed on Jul. 26, 2005, the entire contents of which are incorporated herein by reference.

### BACKGROUND OF THE INVENTION

In recent years, monolithic multiple wavelength lasers have been used. A monolithic multiple wavelength laser is capable of emitting light on at least two wavelengths. For example, the multiple wavelength laser has been used as the laser for reading CDs and writing DVDs.

It may be necessary for a monolithic multiple wavelength laser to have good heat dissipation. Good heat dissipation is needed because the laser element, especially a high optical output laser, generates a large amount of heat.

### SUMMARY

This summary is provided to introduce a selection of concepts in a simplified form that are further described below in the Detailed Description. This summary is not intended to identify key features or essential features of the claimed subject matter.

Aspects of the invention relate to an improved semiconductor laser array and an improved semiconductor laser device.

These and other aspects of the disclosure will be apparent upon consideration of the following detailed description of illustrative embodiments.

### BRIEF DESCRIPTIONS OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross sectional view of a semiconductor laser array, which is mounted on a submount in accordance with a first embodiment of the present invention.

FIG. 2 is a schematic plan view of a semiconductor laser array in accordance with a first embodiment of the present invention.

FIG. 3 is a cross sectional view of a semiconductor laser device in accordance with a first embodiment of the present invention.

FIG. 4 is a graph showing a relationship between a forward current and an optical output of a semiconductor laser element for writing DVDs, which is configured to emit 650 nm laser in accordance with aspects of the present invention.

FIG. 5 is a graph showing a relationship between a forward current and an optical output of a semiconductor laser element for reading CDs, which is configured to emit 780 nm laser in accordance with aspects of the present invention.

FIG. 6 is a cross sectional view of a semiconductor laser array in accordance with a first embodiment of the present invention.

FIGS. 7-11 are perspective views of a semiconductor laser array showing a manufacturing process in accordance with a first embodiment of the present invention.

FIG. 12 is a cross sectional view of a semiconductor laser array in accordance with a comparative example.

FIG. 13 a schematic plan view of a semiconductor laser array in accordance with the comparative example.

FIG. 14 is a cross sectional view of a semiconductor laser device in accordance with the comparative example.

FIG. 15 is a graph showing a relationship between a forward current and an optical output of a semiconductor laser element for writing DVDs, which is configured to emit 650 nm laser, in accordance with the first embodiment of the present invention and the comparative example.

FIG. 16 is a cross sectional view of a semiconductor laser array in accordance with a second embodiment of the present invention.

### DETAILED DESCRIPTION

The various aspects summarized previously may be embodied in various forms. The following description shows by way of illustration of various combinations and configurations in which the aspects may be practiced. It is understood that the described aspects and/or illustrative embodiments are merely examples, and that other aspects and/or illustrative embodiments may be utilized and structural and functional modifications may be made, without departing from the scope of the present disclosure.

Various connections between elements are hereinafter described. It is noted that these connections are illustrated in general and, unless specified otherwise, may be direct or indirect and that this specification is not intended to be limiting in this respect.

Illustrative embodiments of the present invention will be explained with reference to the drawings as follows.

General Overview

In one aspect of the present invention, a semiconductor laser array may include a substrate, and a plurality of semiconductor laser elements monolithically provided on the substrate, having a first laser element and a second laser element, the first laser element configured to emit a shorter wavelength laser than the second laser element; a emission portion of the first laser element provided substantially on a center line of the substrate in a cross sectional view taken along a perpendicular plan to one of an emission direction of the first laser element and an emission direction of the second laser element.

In one aspect of the present invention, a semiconductor laser array, may include a substrate, and a plurality of semiconductor laser elements monolithically provided on the substrate, having at least a first laser element and a second laser element, the first laser element configured to emit a shorter wavelength laser than the second laser element; a ridge stripe of the first laser element provided substantially on a center line of the substrate in a cross sectional view taken along perpendicular plan to one of an emission direction of the first laser element and an emission direction of the second laser element.

In another aspect of the invention, a semiconductor laser device may include a submount, and a semiconductor laser array including, a substrate, and a plurality of semiconductor laser elements monolithically provided on the substrate, having a first laser element and a second laser element, the first laser element configured to emit a shorter wavelength laser than the second laser element; a emission portion of the first laser element provided substantially on a center line of the substrate in a cross sectional view taken along perpendicular plan to one of an emission direction of the first laser element and an emission direction of the second laser element, wherein the semiconductor laser array is mounted on the submount as junction-down.

In yet another aspect of the invention, a semiconductor laser device may include a first laser and a second laser that are both mounted to a substrate. The length directions of the first and second lasers may be parallel to each other, with the first laser being mounted closer to the center of said substrate than said second laser.

### First Illustrative Embodiment

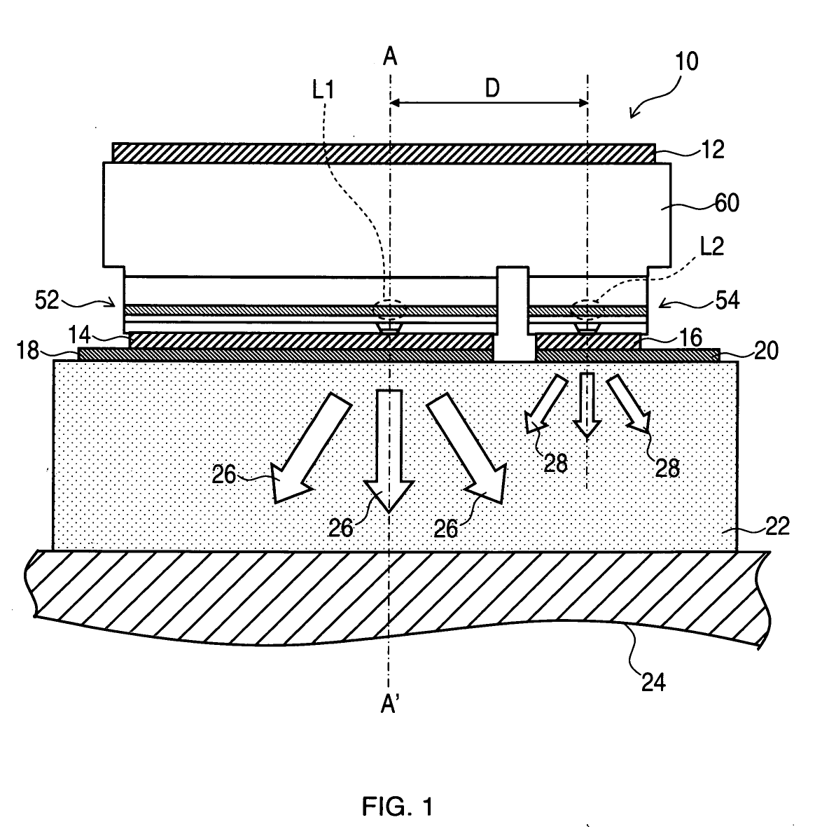

A first illustrative embodiment of the present invention will be explained hereinafter with reference to FIGS. 1-11.

FIG. 1 is a cross sectional view of a semiconductor laser array 10, which is mounted on a submount 22 in accordance with a first illustrative embodiment of the present invention. FIG. 1 is a cross sectional view of the semiconductor laser array 10 taken along perpendicular plan to an emission direction of a first laser element 52 or a second laser element 54. In this illustrative embodiment, the emission directions of the first laser element and the second laser element are parallel to each other.

In the semiconductor laser array 10, the first laser element 52 and the second laser element 54 are provided. The first laser element 52 is configured to emit a first wavelength laser, and the second laser 54 is configured to emit a second wavelength laser. For example, the first wavelength may be 650 nm and the second wavelength may be 780 nm. In other words, the semiconductor laser array 10 is configured to emit two kinds of wavelengths. Accordingly, the semiconductor laser array 10 may be called two-wavelength laser array 10. The first and the second semiconductor laser elements 52, 54 are monolithically provided on a substrate 60. The semiconductor laser array 10 is mounted on an insulating substrate 22 via an Au -Sn eutectic solder (not shown in FIG. 1).

The insulating substrate 22 is made of AlN, SiC or the like, which has good heat conductivity. A first electrode pattern 18 and a second electrode pattern 20 are provided on the top surface of the insulating substrate 22. The first electrode pattern 18 and the second electrode pattern 20 are isolated each other. The semiconductor laser array 10 is provided on the insulating substrate as a junction-down (upside down). Namely, the emission area is provided near the insulating substrate 22. So the heat dissipation efficiency is improved.

A first p side electrode 14 of the first laser element 52 is connected to the electrode pattern 18, and a second p side electrode 16 of the second laser element 54 is connected to the electrode pattern 20.

An n side electrode 12, which is a common electrode of the first laser element 52 and the second laser element 54, is provided on a top surface of the conductive substrate 60. The bias voltage of the first laser element 52 and the second laser element 54 is capable of being added independently.

The insulating substrate (submount) 22 is provided on a metal block 24 with a solder (not shown in FIG. 1). The heat generated at the first and the second laser element 52, 54 is dissipated to the heat block 24 via the insulating substrate 22. A schematic heat flow is shown as arrows 26, 28 in FIG. 1.

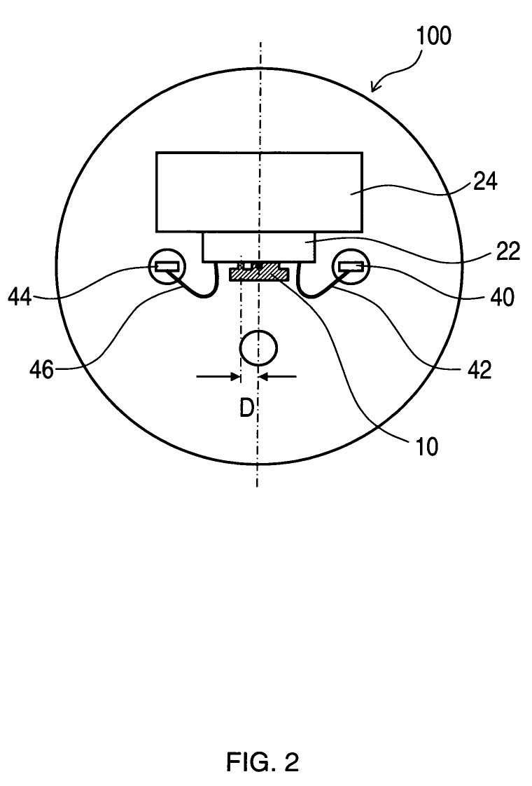

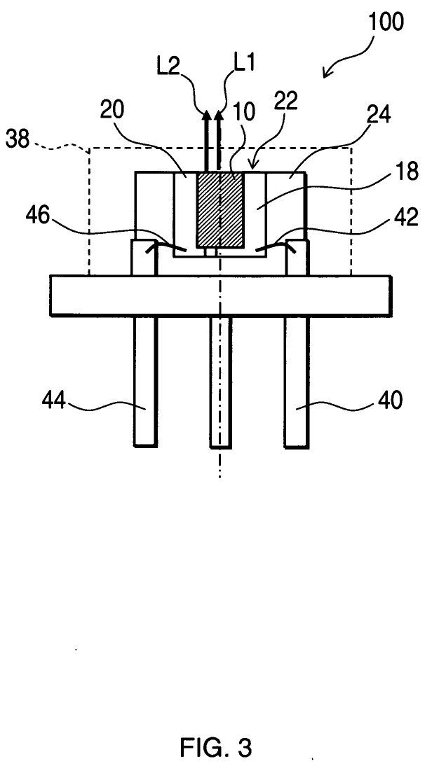

FIGS. 2 and 3 show a can package type semiconductor laser device 100, which has the semiconductor array 10. FIG. 2 is a plan view and FIG. 3 is a perspective view.

In the semiconductor laser device 100, a first lead 40 is connected to the first electrode pattern 18 of the insulating substrate 22 via a wire 42, and a second lead 40 is connected to the second electrode pattern 20 via a wire 46. A cap 38, which has a good transparent ratio and a low reflective index against laser L1 and L2, is provided in the semiconductor laser device 100.

As shown in FIG. 1, the first wavelength laser L1 is emitted from a position, which is on the line A-A′. In other words, the emission portion of the first laser element 52 is on the center line A-A′. The line A-A′ is a line which is a center line of the semiconductor laser array 10 and perpendicular to a top surface or a bottom surface of the semiconductor laser array 10. In this illustrative embodiment, the top and the bottom surfaces of the semiconductor laser array 10 are parallel. Additionally or alternatively, the ridge first wavelength laser L1 may be on the center line of the insulating substrate.

In yet a further perspective, the first wavelength laser L1 may be positioned generally along a line that is the center of mass of the insulating substrate 22.

On the other hand, the second wavelength laser L2 is emitted from a position, which is distance D apart from the emission position of the first laser element 52. The first laser and the second laser are emitted toward a surface of FIG. 1.

The 650 nm laser may have an optical spectrum 650±20 nm. The 780 nm laser may have an optical spectrum 780±30 nm. A later mentioned 405 nm laser may have an optical spectrum 405±20 nm.

It may be preferable that the distance D is no more than 120 μm, or more preferable that the distance D is no more than 110 μm, since the distance D corresponds to the counterpart distance of a two wavelength read only monolithic semiconductor laser device. In case the distance D corresponds to the two wavelength read only monolithic semiconductor laser device, the semiconductor laser device 100, which is applicable to writable semiconductor laser, may be optically compatible with the two wavelength read only semiconductor laser.

In this illustrative embodiment, the semiconductor laser device may be driven in a high power mode in order to obtain high optical output for applying to writing DVDs. The reason the distance D is no more than 120 μm may be mainly to reduce a spherical an aberration or coma aberration.

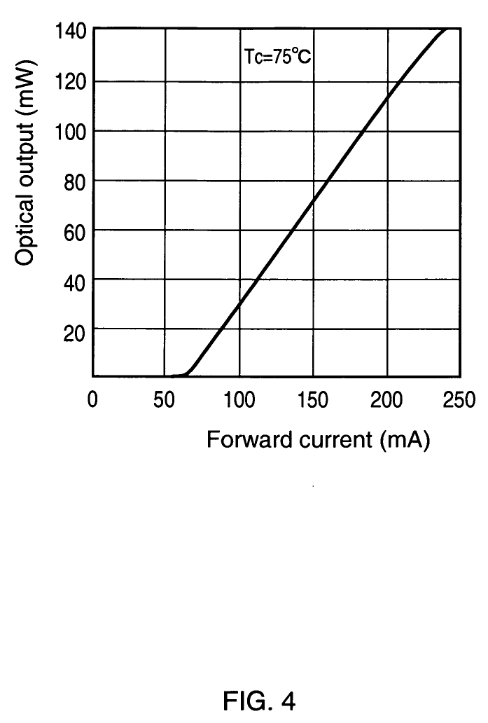

FIG. 4 shows a relationship between a forward current and an optical output of a laser for writing DVD. The optical output of the 650 nm laser is needed more than CW (continuous wave) 100 mW. About 180 mA forward current is needed in order to obtain CW output 100 mA under Tc=75 Centigrade. So about 350 mW power is into heat. On the other hand, the optical output of the laser for CD is needed CW 7 mW under Tc=75 Centigrade.

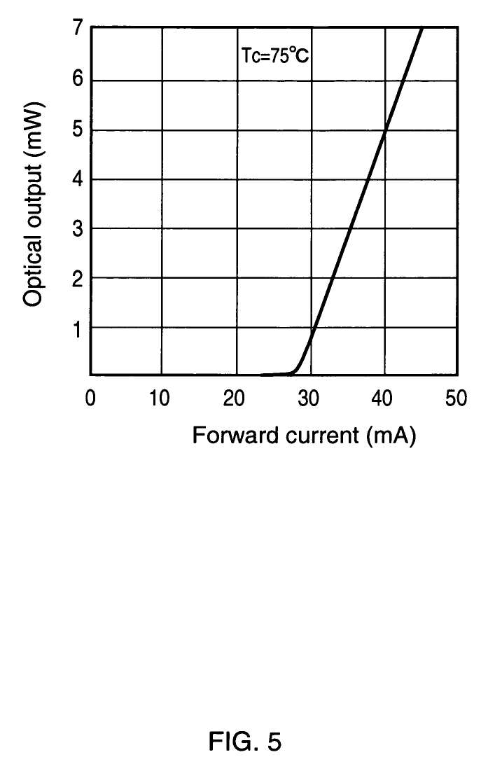

FIG. 5 shows a relationship between a forward current and an optical output of a laser for reading CD. About 88 mW power is converted into heat. This heat is small. That heat is about 25% of the heat generated at the laser for writing DVDs.

The first laser element 52 is provided on a center line A-A′ of the semiconductor laser chip. So heat resistance of the first laser element 52 is increased by providing an even heat dissipation volume below the laser L1. Thus, the heat flow 26, which is generated at the first laser element 52, greatly spread to the insulating substrate 22 and the metal block 24.

The second laser element 54 is provided apart form the center line A-A′. However, the heat generated at the second laser element 54 is smaller than the heat generated at the first laser element 52, since the power consumption of the second laser element 54 is about 25% of the power consumption of the first laser element 52. So the characteristic of the second laser element 54 is worsened by heat more difficultly than that of the first laser element 52.

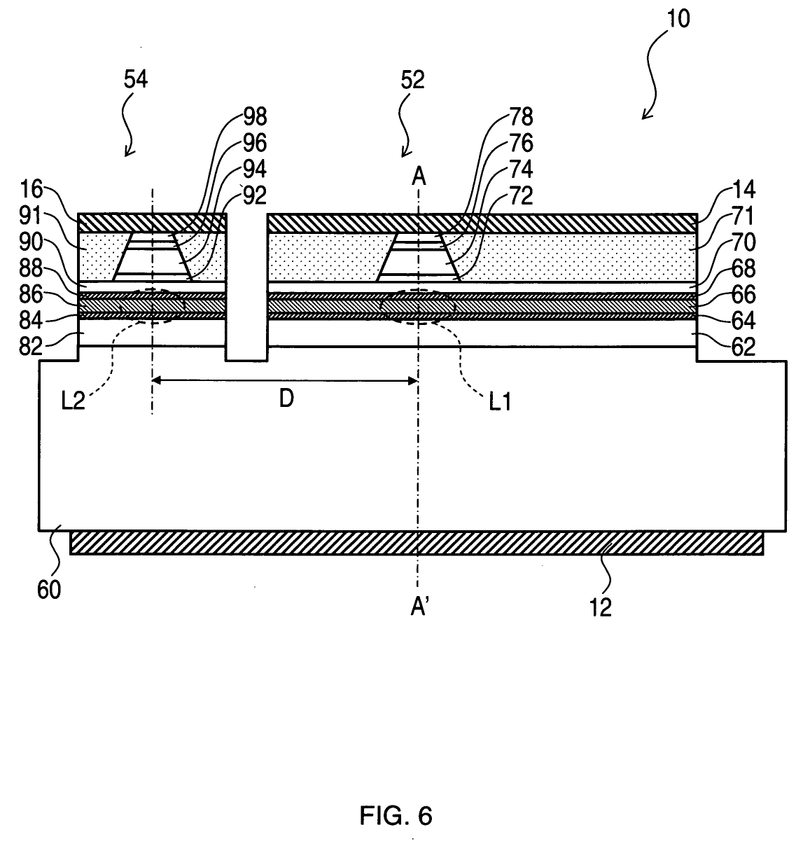

The structure of the semiconductor laser array 10 will be explained hereinafter with reference to FIGS. 6-11.

FIG. 6 is a cross sectional view of the semiconductor laser array 10.

The first laser element 52, which is configured to emit first wavelength laser L1 (e.g. 650 nm), and the second laser element 54, which is configured to emit second wavelength laser L2 (e.g. 780 nm), are provided on the conductive substrate 60, such as GaAs.

The structure of the semiconductor laser array 10 will be explained with its manufacturing process.

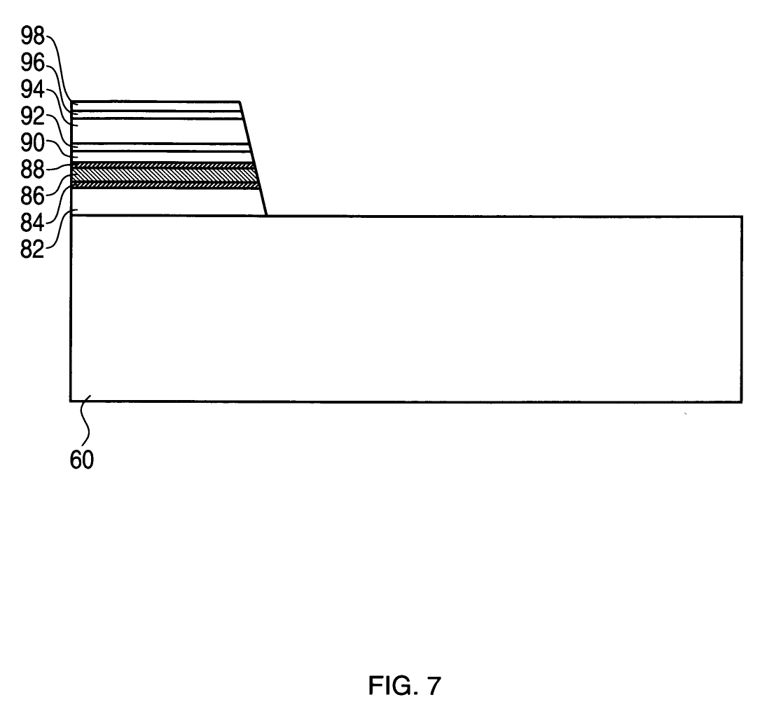

As shown in FIG. 7, an n type InGaAlP cladding layer 82, an n type InGaAlP optical guide layer 84, a MQW active layer 86, a p type InGaAlP optical guide layer 88, a p type InGaAlP cladding layer 90, a p type InGaP etching stop layer 92, a p type InGaAlP cladding layer 94, a p type InGaP intermediate layer 96, and a p type GaAs contact layer 98 are grown on the substrate 60 in this order. Above mentioned lamination layers are left in a portion corresponding to the second laser element 54. In FIG. 7, the left part of the lamination layers remain. The other part (right part in FIG. 7) is removed by, for example, etching.

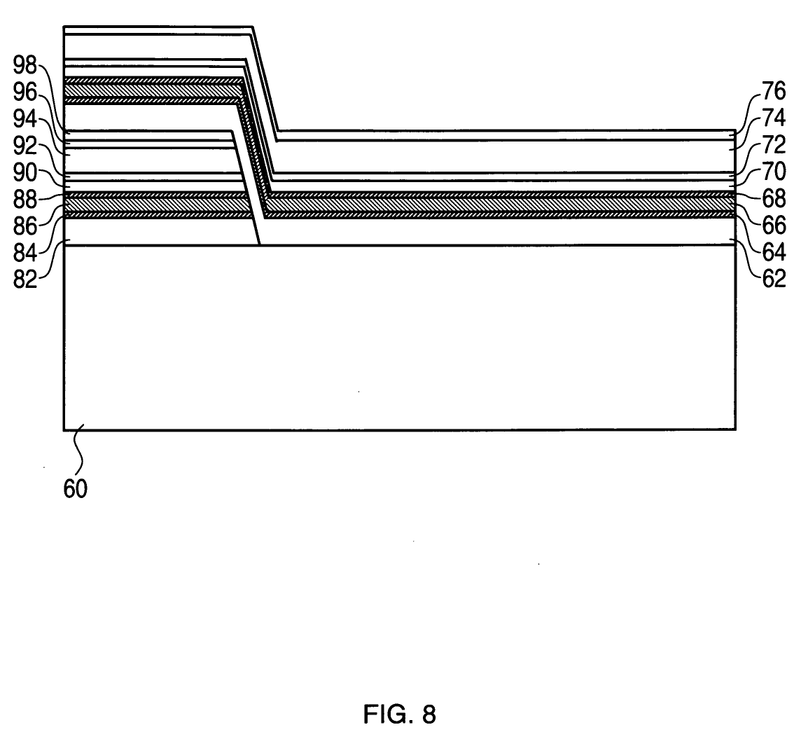

As shown in FIG. 8, an n type InGaAlP cladding layer 62 an n type InGaAlP optical guide layer 64, an MQW active layer 66, a p type InGaAlP optical guide layer 68, a p type InGaAlP cladding layer 70, a p type InGaP etching stop layer 72, a p type InGaAlP cladding layer 74, a p type InGaP intermediate layer 76, and a p type GaAs contact layer 78 are grown on the substrate 60 and the lamination layers.

The semiconductor layers may be formed by MOCVD (Metal Organic Chemical Vapor Deposition) method, MBE (Molecular Beam Epitaxy) method or the like.

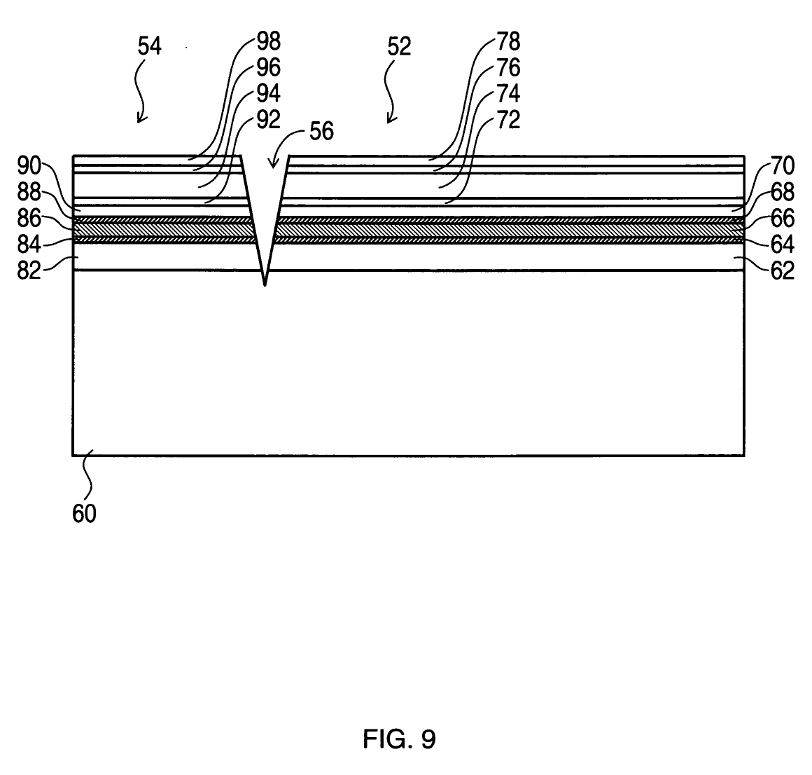

As shown in FIG. 9, semiconductor layers provided on the lamination layers in a position where the second laser element 54 is provided is removed.

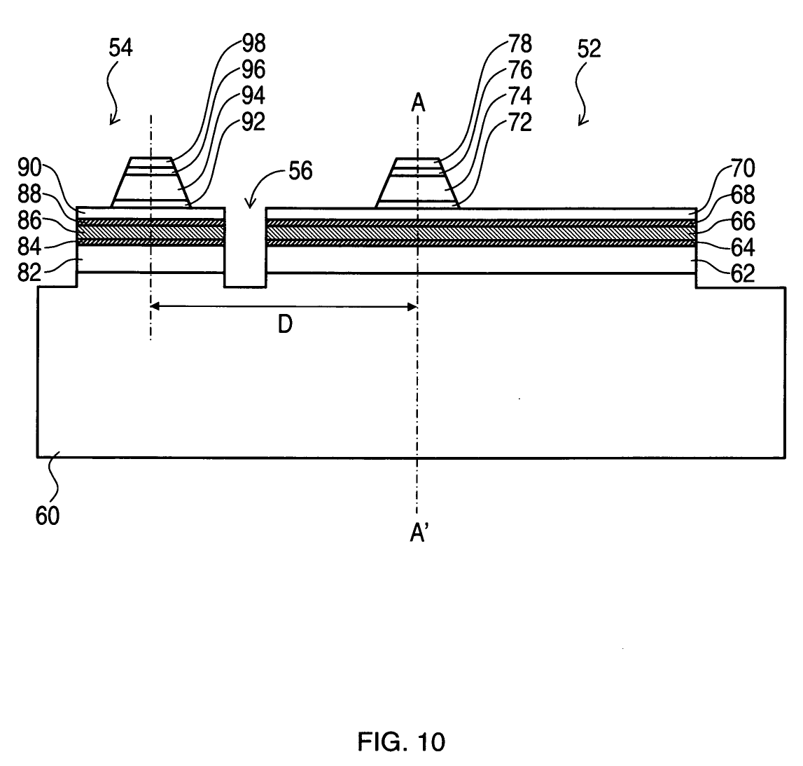

As shown in FIG. 10, the ridge stripe including the p type etching stop layers 72, 92, the p type InGaAlP cladding layers 74, 94, the p type InGaP intermediate layer 76, 96, the p type GaAs contact layers 78, 98 are formed. A trench 56, which reaches the substrate 60, is provided between the first laser element 52 and the second laser element 54.

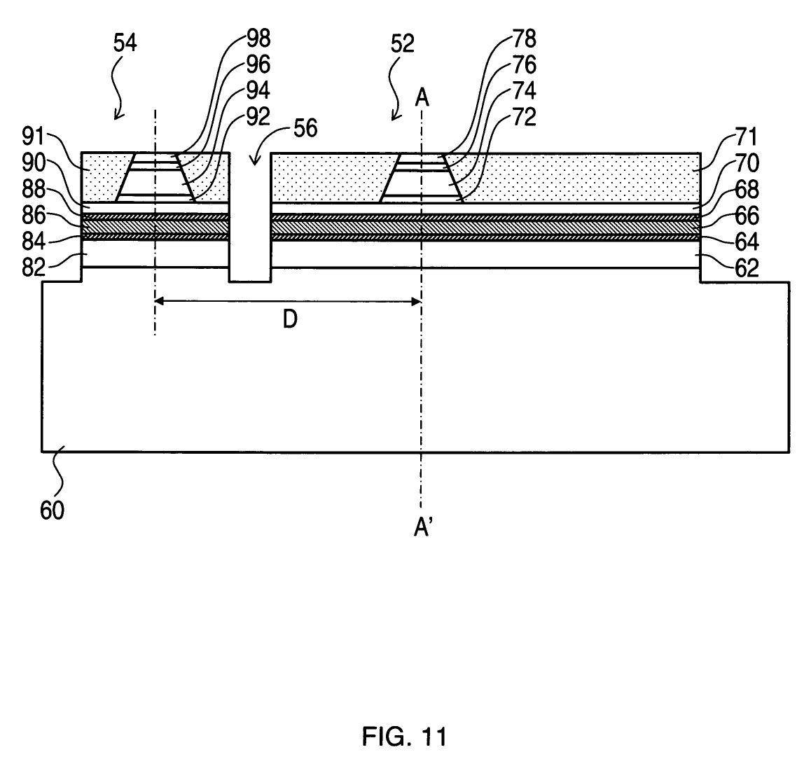

As shown in FIG. 11, insulating layers 71, 91 are deposited and patterned.

The p side electrodes 14, 16 and the n side electrode 12 are provided, and the semiconductor laser array as shown in FIG. 6 is created.

The first laser element 52 is a portion from the n type InGaAlP cladding layer 62 to the first p side electrode 14. The second laser element 54 is a portion from the n type InGaAlP cladding layer 82 to the second p side electrode 16.

It is preferable that the height of the first laser element 52 and the second laser element 54 is substantially the same, since the semiconductor laser array 10 can be mounted as junction-down, meaning that the lasers are mounted with their tops closest to insulating substrate 22. The chip width of the semiconductor laser array 10 may be 280-400 μm. In this illustrative embodiment, the chip width corresponds to the width of the substrate 60.

The MQW active layer 66 of the first laser element 52 emitting 650 nm laser has an In0.5Ga0.5As well layer and an In0.5(Ga0.5Al0.5)P barrier layer. The MQW active layer 86 of the second laser element 54 emitting 780 nm laser has a Ga0.9Al0.1As well layer and a Ga0.65Al0.35As barrier layer. The active layer of the first laser element 52 and the second laser element 54 may be not MQW structure.

The ridge stripe of the first laser element 52 and the second laser element 54 may be a real index refractive index type laser, which can easily obtain high optical output. The width of the ridge stripe at its bottom may be 1.0-2.0 μm, the width of the ridge stripe at its top may be 0.5-1.5 μm, and the height of the ridge stripe may be 1.0-5.0 μm.

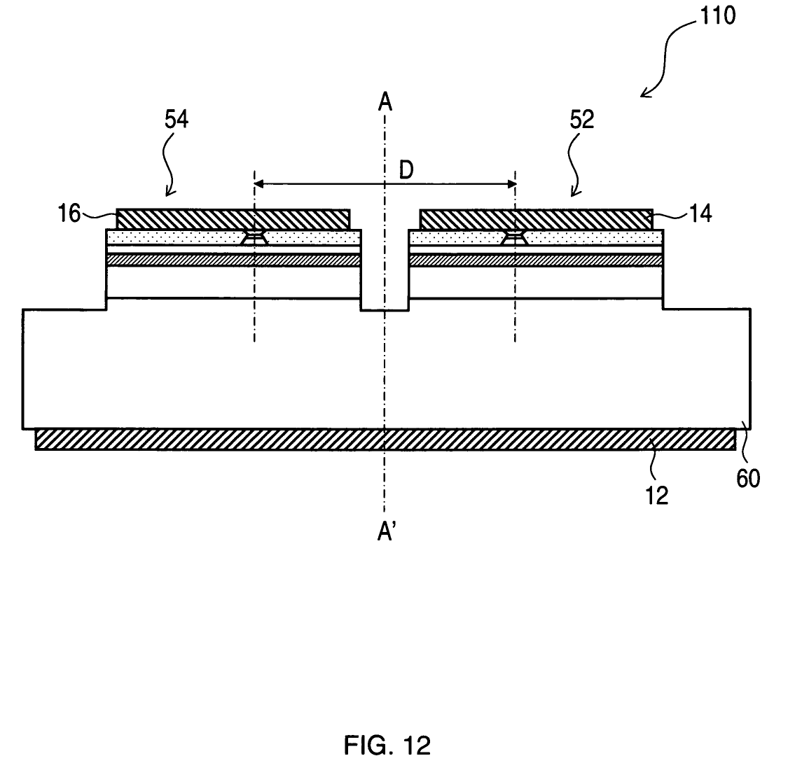

The comparative example of the first illustrative embodiment will be explained hereinafter with reference to FIGS. 12-14.

FIG. 12 shows a two wavelength semiconductor laser array 110 of the comparative example. The first laser element 52 and the second laser element 54, which are monolithically provided on the substrate 60, are symmetric to the center line A-A′. The distance D between the emission portion of the first laser element 52 and the second laser element 54 is no more than 120 μm. The first laser element 52, which is for writing DVDs and is configured to emit 650 nm laser, is driven by a high current.

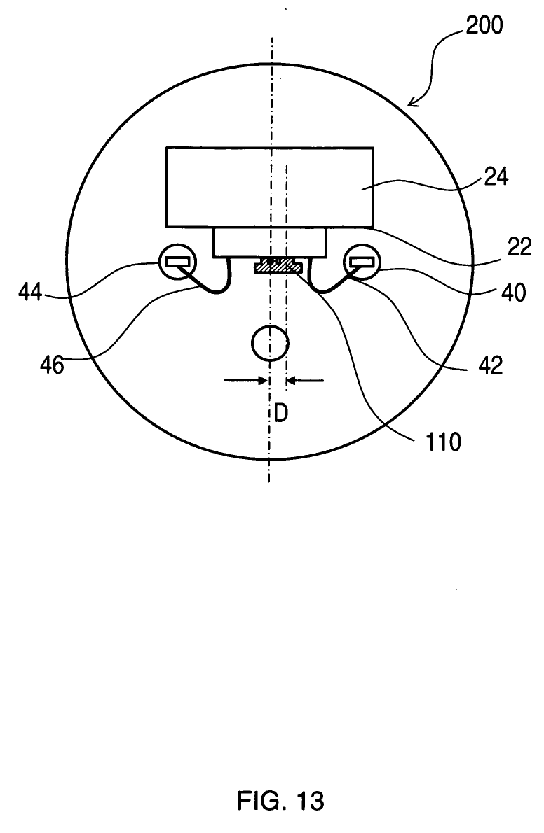

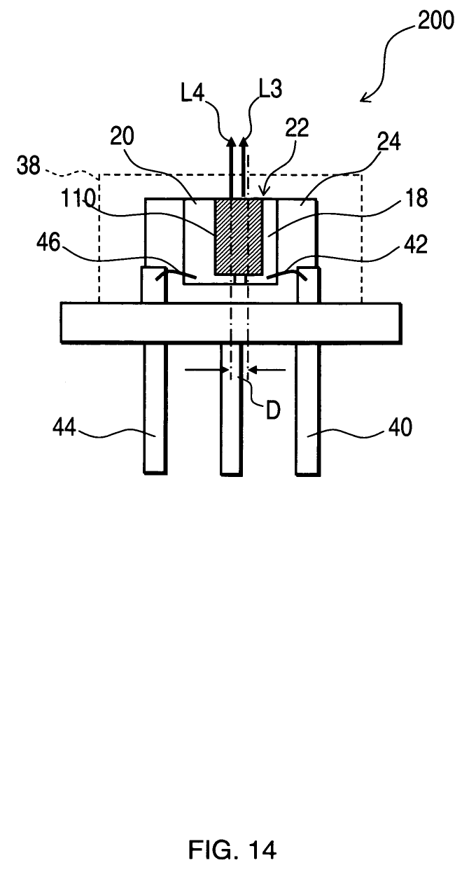

FIGS. 13 and 14 show a can package type semiconductor laser device 200, which has the semiconductor array 110. FIG. 13 is a plan view and FIG. 14 is a perspective view. With respect to each portion of FIGS. 13 and 14, the same or corresponding portions of the semiconductor laser device as shown in FIGS. 2 and 3 are designated by the same reference numerals, and explanation of such portions is omitted.

Generally a requirement of an aberration for writing DVDs is more severe than that for the recording CDs. So, as shown in FIGS. 13 and 14, the first laser element which emits laser L4 is provided on the center of the package. The laser element emitting laser L4 is provided on the center of the package, but is not provided in the center of the chip. So the heat dissipation ratio of the comparative example is worse than that of the first illustrative embodiment. This is at least partially due to the more powerful laser having less of a heat sink next to it. The heat generated by the more powerful laser in the comparative example cannot be as readily dissipated as that shown in the first illustrative embodiment.

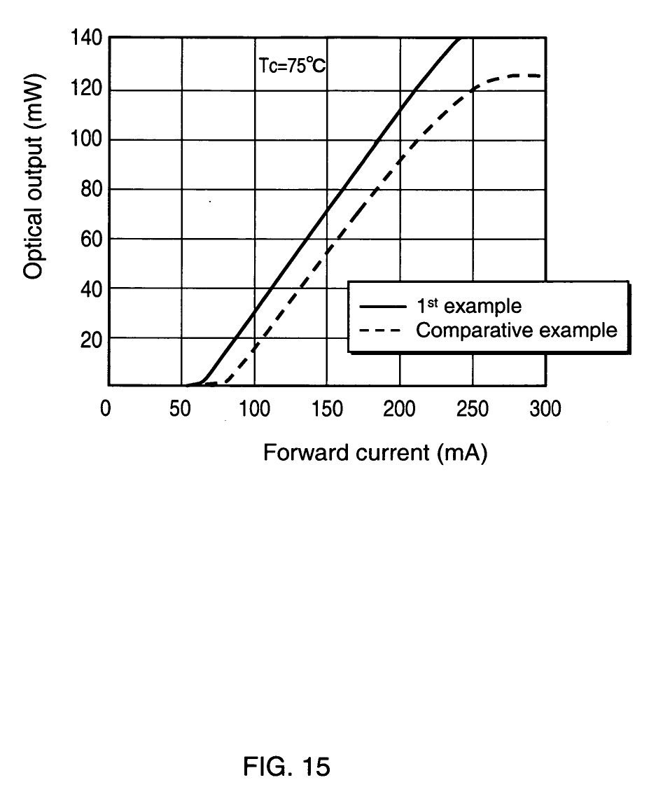

FIG. 15 shows a relationship between the forward current and the optical output in accordance with the first illustrative embodiment and the comparative example, when the Tc=75 Centigrade.

In the comparative example, the optical output is saturated to near 125 mW, when the forward current is over 250 mA. This characteristic does not meet the requirement of DVD-RW. However, in the first illustrative embodiment, the optical output 140 mW or more may be obtained with the same forward current. So the semiconductor laser array of the first illustrative embodiment may be applicable to DVD-RW.

According to heat analysis using ANSYS (finite element analysis program), the hetero junction temperature of the first laser element 52 of the first illustrative embodiment is about 87 Centigrade at its maximum. However, the hetero junction temperature of the first laser element 52 of the comparative example is about 93 Centigrade at its maximum, which is an over oscillation temperature.

### Second illustrative Embodiment

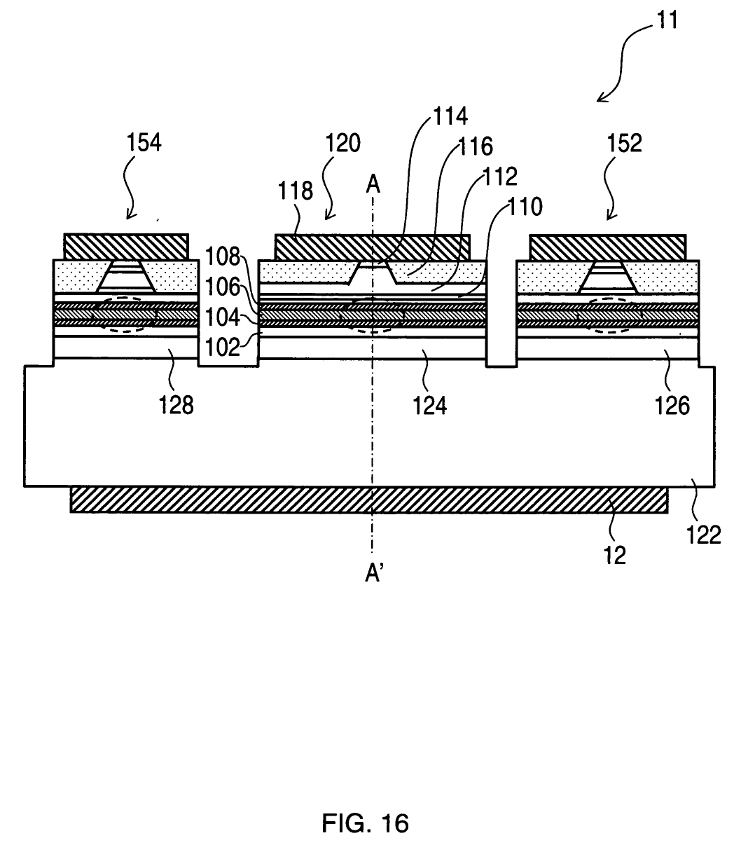

A second illustrative embodiment is explained with reference to FIG. 16.

A semiconductor laser array 11 is described in accordance with a second illustrative embodiment of the present invention. With respect to each portion of this illustrative embodiment, the same or corresponding portions of the semiconductor laser array 10 of the first illustrative embodiment shown in FIGS. 1-15 are designated by the same reference numerals, and explanation of such portions is omitted.

FIG. 16 shows a cross sectional view of the semiconductor laser array 11, taken along perpendicular plan to an emission direction of a first laser element 120, a second laser element 152, and a third laser element 154.

In this second illustrative embodiment, the first laser element 120, which is configured to emit 405 nm wavelength laser, is provided in a center of the laser chip 11.

In the semiconductor laser array 11, the first laser element 120, the second laser element 152, which is configured to emit 650 nm laser, and the third laser element 154 are monolithically provided on a substrate 122, such as SiC.

The first laser element 120, which is GaN based semiconductor laser and is configured to emit blue violet laser, has a high operating voltage, about 4.5V. The forward current is needed in order to obtain CW 100 mW in Tc=75 Centigrade. The electronic power is about 575 mW, and the heat generated by the 405 nm laser may be 1.6 times of the heat generated by the 650 nm laser element. So, the first laser element 120 is provided in a center portion of the chip, such that the heat dissipation efficiency is improved. The second laser element 152 and the third laser element 154 is preferably provided opposite side with interposing the first laser element 120.

The distance between the first laser element 120 and the second laser element 152 is preferably no more than 120 =82 m. The distance between the first laser element 120 and the third laser element 154 is preferably no more than 120 μm.

The structure of the three wavelength semiconductor laser array 11 will be explained hereinafter.

In the first laser element 120, a GaN buffer layer 124, an n type AlGaN cladding layer 102, an n type GaN optical guide layer 104, an MQW active layer 106, a p+ type AlGaN overflow blocking layer 108, a p type optical guide layer 110, a p type AlGaN cladding layer 112, and a p+ type GaN contact layer 114 are provided on the SiC substrate 122 un this order. The p type AlGaN cladding layer 112 has a stripe shape, and an insulating layer 116 is provided on a side of the ridge. Laser is confined to horizontal direction. The first laser element 120 is a real refractive index guide structure laser, so high optical laser may be obtained. The first laser element 120 is a portion from the n type AlGaN cladding layer 102 to the first p side electrode 118. The width of the ridge stripe at its bottom is 1-3 μm, and the height of the ridge stripe is 0.1-1.0 μm.

The second laser element 152 corresponds to laser element 52 shown in FIG. 6, and the third laser element 154 corresponds to laser element 54 in FIG. 6. N type GaAs buffer layers 126, 128 are provided between the SiC substrate 122 and the n type cladding layers. The height of the first, second, and third laser element may be substantially same so as to being mounted on a submount as junction-down.

The first laser element 120 may be formed at first, since the growth temperature of GaN or AlGaN using MOCVD is high, such as about 1000 Centigrade, with comparing to the growth temperature, 700-850 Centigrade. However the manufacturing order of the first, second, third laser elements is not limited to this.

In this second illustrative embodiment, the first laser element, which generates larger heat, is provided substantially center of the semiconductor laser array (semiconductor chip). So heat dissipate efficiency is improved.

In the comparative example as shown in FIG. 12, the optical distortion may be decreased, when an emission center of one of the laser elements is adjusted to the optical axis and adjusted to center axis of laser package.

In the comparative example, the emission centers are not provided in the center of the semiconductor laser device. So it may be hard that the semiconductor laser array is mounted on the package precisely. So the productivity of manufacturing semiconductor laser device may be worsened.

However it may be easy that the semiconductor laser array in accordance with the first or the second illustrative embodiment is mounted in package easily, since one of the emission center of the semiconductor array is provided in center of the chip.

The emission portion of the laser element may be not just on the center line of the semiconductor laser array. Alternatively, the ridge of the first laser element may be on the center line of the semiconductor laser array. Heat dissipation efficiency may be improved by this arrangement.

Illustrative embodiments of the invention have been described with reference to the examples. However, the invention is not limited thereto.

For example, the material of the semiconductor laser element is not limited to InGaAlP-based or GaN-based semiconductors, but may include various other Group III-V compound semiconductors such as GaAlAs-based and InP-based semiconductors, or Group II-VI compound semiconductors, or various other semiconductors.

Other embodiments of the present invention will be apparent to those skilled in the art from consideration of the specification and practice of the invention disclosed herein. It is intended that the specification and embodiments be considered as illustrative only, with a true scope and spirit of the invention being indicated by the following claims.

What is claimed is:

1. A semiconductor laser array, comprising:
a substrate; and
a plurality of semiconductor laser elements monolithically provided on the substrate, the plurality of semiconductor laser elements including at least a first laser element and a second laser element, the first laser element configured to emit a shorter wavelength laser than the second laser element, the first laser element including a emission portion provided substantially on a center line of the substrate in a cross sectional view taken along a perpendicular plan to one of an emission direction of the first laser element and an emission direction of the second laser element.

2. A semiconductor laser array of claim 1, wherein the first laser element is configured to emit higher optical output than the second laser element.

3. A semiconductor laser array of claim 1, wherein the first laser element is configured to emit a 650 nm laser and the second laser element is configured to emit a 780 nm laser.

4. A semiconductor laser array of claim 1, further comprising:
a third laser element configured to emit longer wavelength laser than the second laser element.

5. A semiconductor laser array of claim 4, wherein the first laser element is configured to emit a 405 nm laser, the second laser element is configured to emit a 650 nm laser, and the third laser element is configured to emit 780 nm laser.

6. A semiconductor laser array of claim 1, wherein the first laser element is configured to generate more heat than the second laser element.

7. A semiconductor laser array, comprising:
a substrate; and
a plurality of semiconductor laser elements monolithically provided on the substrate, having at least a first laser element and a second laser element, the first laser element configured to emit a shorter wavelength laser than the second laser element; the first laser element including a ridge stripe provided substantially on a center line of the substrate in a cross sectional view taken along perpendicular plan to one of an emission direction of the first laser element and an emission direction of the second laser element.

8. A semiconductor laser array of claim 7, wherein the first laser element is configured to emit higher optical output than the second laser element.

9. A semiconductor laser array of claim 7, wherein the first laser element is configured to emit a 650 nm laser and the second laser element emit a 780 nm laser.

10. A semiconductor laser array of claim 7, further comprising a third laser element configured to emit a longer wavelength laser than the second laser element.

11. A semiconductor laser array of claim 10, wherein the first laser element is configured to emit a 405 nm laser, the second laser element is configured to emit a 650 nm laser, and the third laser element is configured to emit a 780 nm laser.

12. A semiconductor laser array of claim 7, wherein the first laser element is configured to generate more heat than the second laser element.

13. A semiconductor laser array, comprising:
a submount; and
a semiconductor laser array, said semiconductor laser array including
a substrate, and
a plurality of semiconductor laser elements monolithically provided on the substrate, having a first laser element and a second laser element, the first laser element configured to emit a shorter wavelength laser than the second laser element; a emission portion of the first laser element provided substantially on a center line of the substrate in a cross sectional view taken along perpendicular plan to one of an emission direction of the first laser element and an emission direction of the second laser element,
wherein the semiconductor laser array is mounted on the submount in a junction-down position.

14. A semiconductor laser array of claim 13, wherein the first laser element is configured to emit a higher optical output than the second laser element.

15. A semiconductor laser array of claim 13, wherein the first laser element is configured to emit a 650 nm laser and the second laser element emit a 780 nm laser.

16. A semiconductor laser array of claim 13, further comprising a third laser element configured to emit a longer wavelength laser than the second laser element.

17. A semiconductor laser array of claim 16, wherein the first laser element is configured to emit a 405 nm laser, the second laser element is configured to emit a 650 nm laser, and the third laser element is configured to emit a 780 nm laser.

18. A semiconductor laser array of claim 13, wherein the first laser element is configured to generate more heat than the second laser element.

19. A semiconductor laser array, comprising:
a substrate having center line; and
a plurality of semiconductor laser elements provided on the substrate, the plurality of semiconductor laser elements each having a length and width where the length is longer than the width, said semiconductor laser elements including at least a first laser element that emits a first laser and a second laser element that emits a second laser, the first laser element generating more heat than the second laser element,
wherein the first laser element is mounted closer to said center line, with the length of said first laser element being arranged parallel to said centerline, than said second laser element.

20. The semiconductor laser array of claim 19, wherein said center line of said substrate is a line that bisects a surface of said substrate.
